(19) United States
(12) Patent Application Publication
(10) Pub. No.: US 2011/0156551 A1
(43) Pub. Date: Jun. 30, 2011

(54) CASING STRUCTURE OF ELECTRONIC APPARATUS

(75) Inventors: Naoto Akiyama, Osaka (JP); Takahiro Kitai, Osaka (JP)

(73) Assignee: SANYO ELECTRIC CO., LTD., Osaka (JP)

(21) Appl. No.: 12/977,508

(22) Filed: Dec. 23, 2010

(30) Foreign Application Priority Data
Dec. 25, 2009 (JP) 2009-295770

(51) Int. Cl. H05K 5/02

(52) U.S. Cl. 312/223.1

(57) ABSTRACT

In a casing structure of an electronic apparatus according to the present invention, a chassis is installed inside a casing. The casing includes a metal cabinet component and a resin cabinet component that are provided on two sides of the chassis so as to be coupled with each other. A tongue piece that protrudes in a direction approaching the resin cabinet component is formed in the metal cabinet component. A latching hole is formed in the tongue piece. A latching claw capable of penetrating the latching hole of the tongue piece is protrudingly provided in the resin cabinet component. The resin cabinet component is latched to the metal cabinet component by the latching claw penetrating the latching hole in a direction from the outer side of the tongue piece towards the inner side of the casing.

This patent application claims priority based on Japanese Patent Application No. 2009-295770, the contents of which are hereby incorporated in its entirety by reference into the present application.

### BACKGROUND OF THE INVENTION

1. Field of the Invention

The present invention relates to a casing structure of an electronic apparatus such as a video camera.

2. Description of the Related Art

Conventionally, as this kind of casing structure, a structure has been proposed that includes a pair of cabinet half-bodies that compose a cabinet and a connection member made of metal that connects the two cabinet half-bodies, and in which the pair of cabinet half-bodies are fastened by screws to the connection member.

In the process of assembling an electronic apparatus that includes this kind of casing structure, it is usual to perform temporary fixing by means of a hook mechanism before finally fastening the structure with screws. The hook mechanism is implemented by an engagement structure that elastically engages and disengages. However, in the case of a casing structure in which temporary fixing is performed by means of a hook mechanism, there is a risk that the engagement will be easily disengaged by an impact if the casing structure drops or falls or the like and the casing will disassemble.

When a hook mechanism with a large engaging depth is adopted to solve this problem, a large force is required for engagement and disengagement operations, and maintenance work is difficult. In particular, in a case where one cabinet half-body is made of synthetic resin and the other cabinet half-body is made of metal, it is difficult to obtain a deep engagement.

Further, there is a certain degree of looseness in the hook mechanism for design tolerance purposes. Consequently, assembling errors occur among components in the casing that is in a temporarily fixed state. Hence, not only is it difficult to perform the fastening work using screws thereafter, but there is also the problem that a large number of screws are required for a fastening structure that uses screws.

### SUMMARY OF THE INVENTION

A casing structure of an electronic apparatus according to the present invention has a casing inside which a chassis to which a plurality of components are to be mounted is installed, the casing including a metal cabinet component and a resin cabinet component that are provided on two sides of the chassis so as to be coupled with each other, wherein: one or a plurality of tongue pieces that protrude in a direction approaching the resin cabinet component are formed in the metal cabinet component, and a latching hole is formed in each tongue piece; one or a plurality of latching claws that are capable of penetrating the latching hole of the one or a plurality of tongue pieces are provided in a protruding condition in the resin cabinet component, and the resin cabinet component is latched to the metal cabinet component by the latching claw penetrating the latching hole from an outer side of the tongue piece towards an inner side of the casing; and the resin cabinet component is fastened to the chassis by one or a plurality of screws.

### BRIEF DESCRIPTION OF THE DRAWINGS

FIG. 1 is a perspective view, as seen from the front, of an open state of a video camera that is an embodiment of the present invention;

FIG. 2 is a perspective view, as seen from the rear, of an open state of the video camera;

FIG. 3 is a back view of a closed state of the video camera as seen from the rear;

FIG. 4 is a back view of a first casing included in the video camera as seen from the rear;

FIG. 5 is a side view of the first casing;

FIG. 6 is an exploded perspective view of the first casing;

FIG. 7 is an exploded perspective view of the first casing as seen from a different direction;

FIG. 8 is an exploded perspective view of the first casing as seen from another different direction;

FIG. 9 is a cross-sectional view of the first casing along a line A-A in FIG. 5;

FIG. 10 is a cross-sectional view in which principal parts in FIG. 9 are shown in an enlarged manner; and

FIG. 11 is a cross-sectional view of the first casing along a line B-B in FIG. 5.

### DETAILED DESCRIPTION OF THE PREFERRED EMBODIMENTS

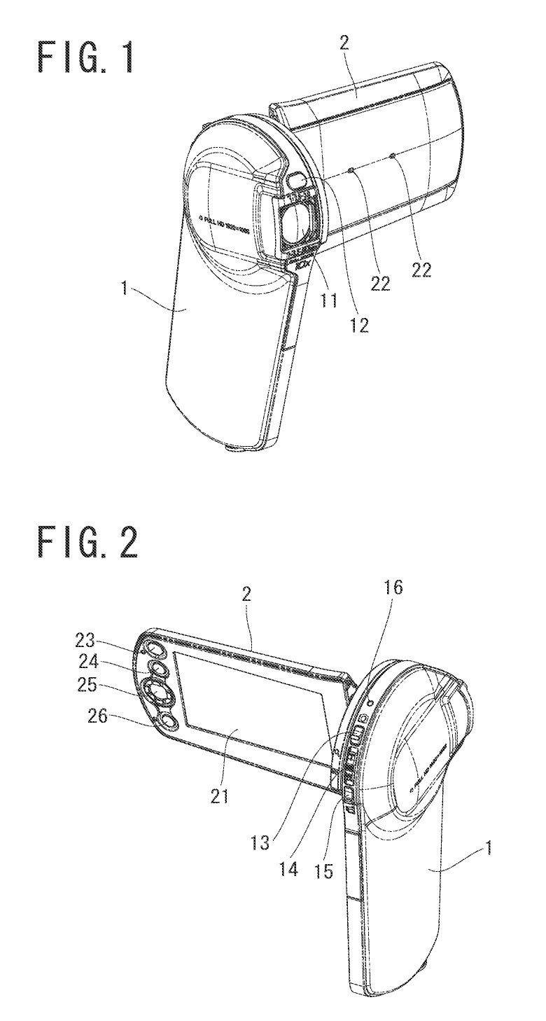

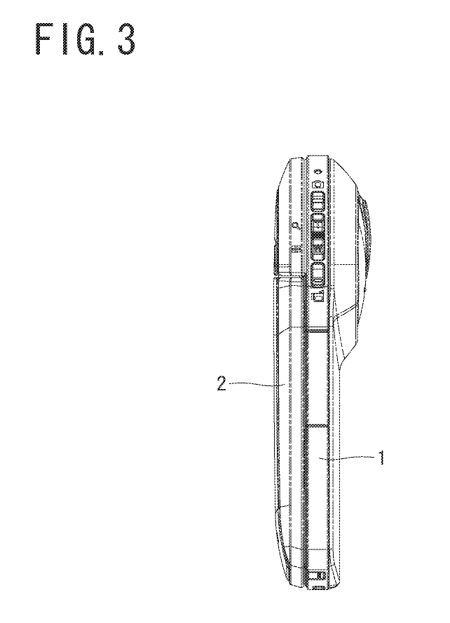

Hereinafter, embodiments of the present invention implemented on a video camera capable of shooting a still image and a moving image will be described in detail with reference to the drawings. A video camera that is an embodiment of the present invention includes, as illustrated in FIGS. 1 and 2, a first casing 1 and a second casing 2. The two casings 1 and 2 are coupled with each other so as to be openable and closeable by a biaxial hinge mechanism (omitted from the drawings). It is possible to set an open state that is illustrated in FIGS. 1 and 2, and a closed state that is illustrated in FIG. 3. As illustrated in FIGS. 1 and 2, the video camera is used by gripping a lower part of the first casing 1 while the second casing 2 is in an open state.

As illustrated in FIGS. 1 and 2, a shooting lens 11 and an LED for illumination 12 are provided on a front part of the first casing 1. In addition, a shutter button 13 and a zoom button 14 that are used to input an instruction for still image shooting, a recording button 15 that is used to input an instruction for moving image shooting, and an access lamp 16 are provided on a rear part of the first casing 1.

A liquid crystal display 21 is provided on an inner face of the second casing 2. A pair of microphones 22 and 22 are provided on the outer face of the second casing 2. A record/playback key 23, a menu key 24, a cross key 25, and a set key 26 are provided at a side of the liquid crystal display 21 on the inner face of the second casing 2. A plating process is performed on the outer face of the second casing 2.

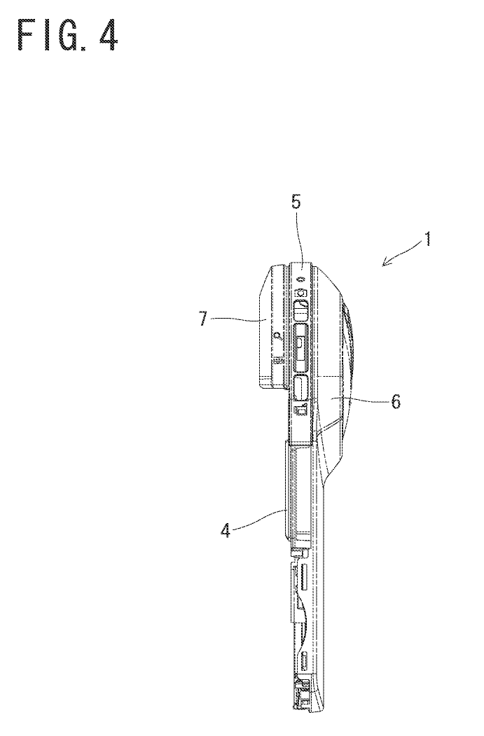

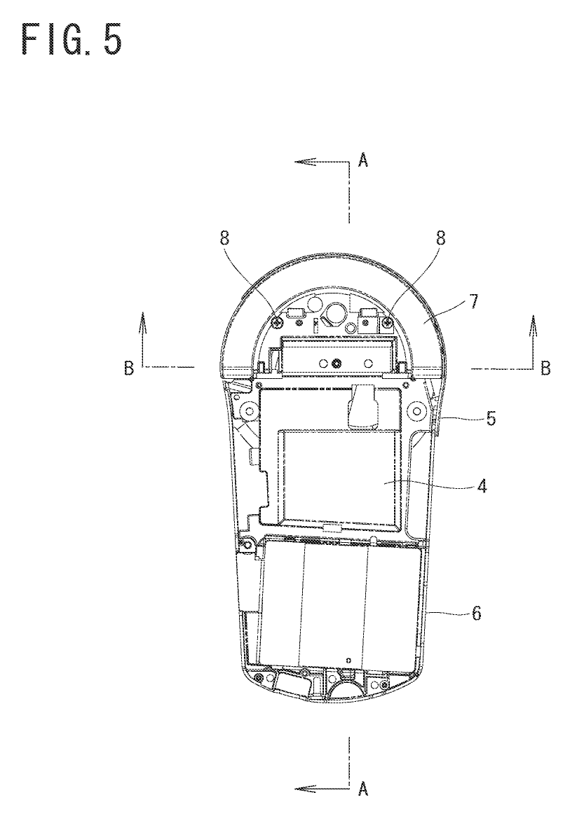

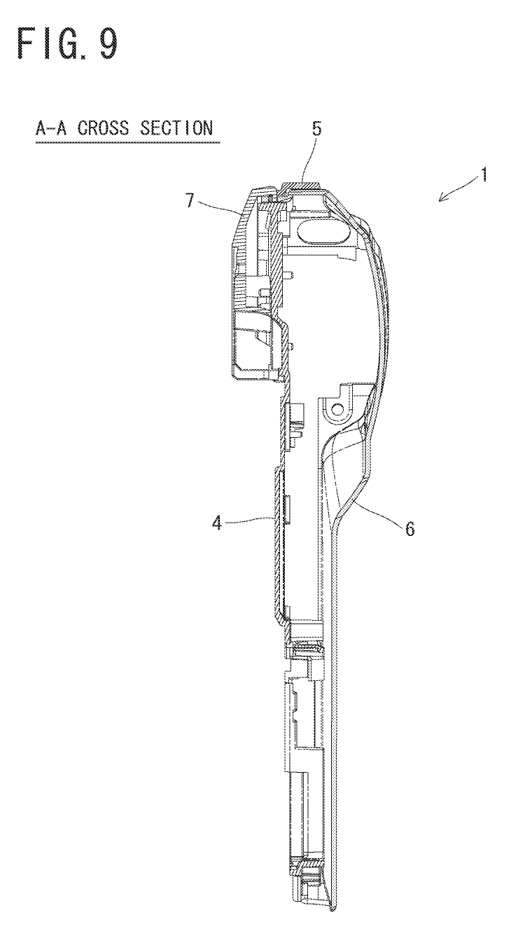

As illustrated in FIGS. 4, 5, and 9, a chassis 4 that is made of synthetic resin and onto which a plurality of components (omitted from the drawings) are to be mounted is installed inside the first casing 1.

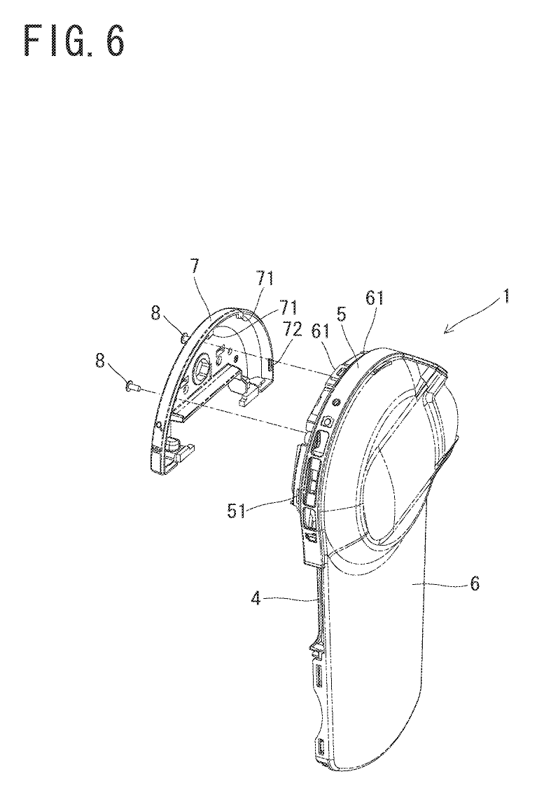

As shown in FIG. 6, the casing 1 includes an intermediate cabinet component 5 made of synthetic resin that curves in an arc shape along an outer circumferential face of the head of the chassis 4, a metal cabinet component 6 made of aluminum that is provided so as to cover a right side face of the chassis 4, and a resin cabinet component 7 made of synthetic resin that is provided so as to cover a part (an approximately semicircular region) of a left side face of the chassis 4.

The metal cabinet component 6 and the intermediate cabinet component 5 are disengageably latched by a publicly known hook mechanism to the chassis 4.

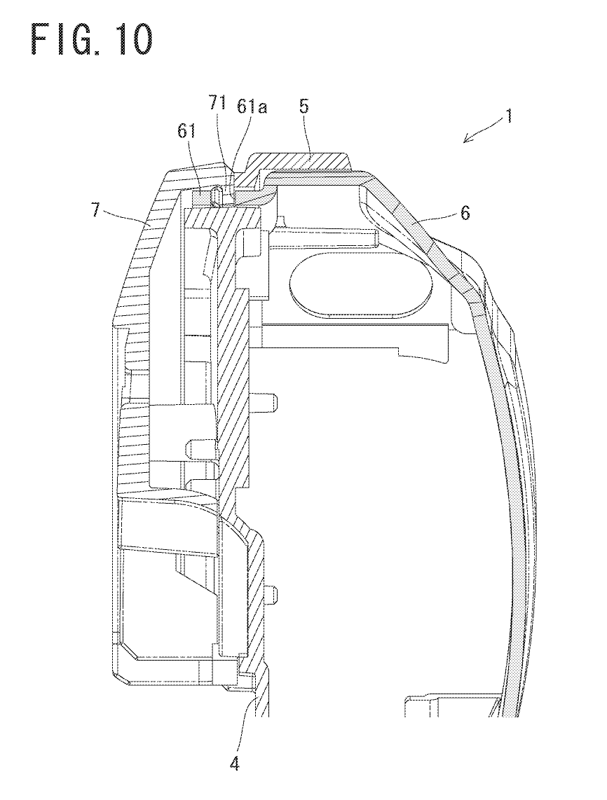

As illustrated in FIGS. 6 to 8, two tongue pieces 61 and 61 that protrude in a direction approaching the resin cabinet component 7 are formed in the metal cabinet component 6. As illustrated in FIG. 10, a latching hole 61a is formed in each tongue piece 61. Further, as illustrated in FIGS. 6 to 8, two latching claws 71 and 71 that are capable of penetrating the latching hole 61a of each tongue piece 61 are provided in the resin cabinet component 7 in a condition in which the latching claws 71 and 71 protrude toward the inside of the first casing 1.

As illustrated in FIG. 10, the tongue piece 61 of the metal cabinet component 6 passes through the inside of the intermediate cabinet component 5 and protrudes to the resin cabinet component 7 side. Each latching claw 71 of the resin cabinet component 7 penetrates the corresponding latching hole 61a in a direction from the outer side of the tongue piece 61 towards the inner part of the casing 1 to thereby latch an end part of the resin cabinet component 7 to an end part of the metal cabinet component 6. Further, two engagement protrusions 72 and 72 that protrude towards the inside of the first casing 1 are formed at two end parts of the resin cabinet component 7.

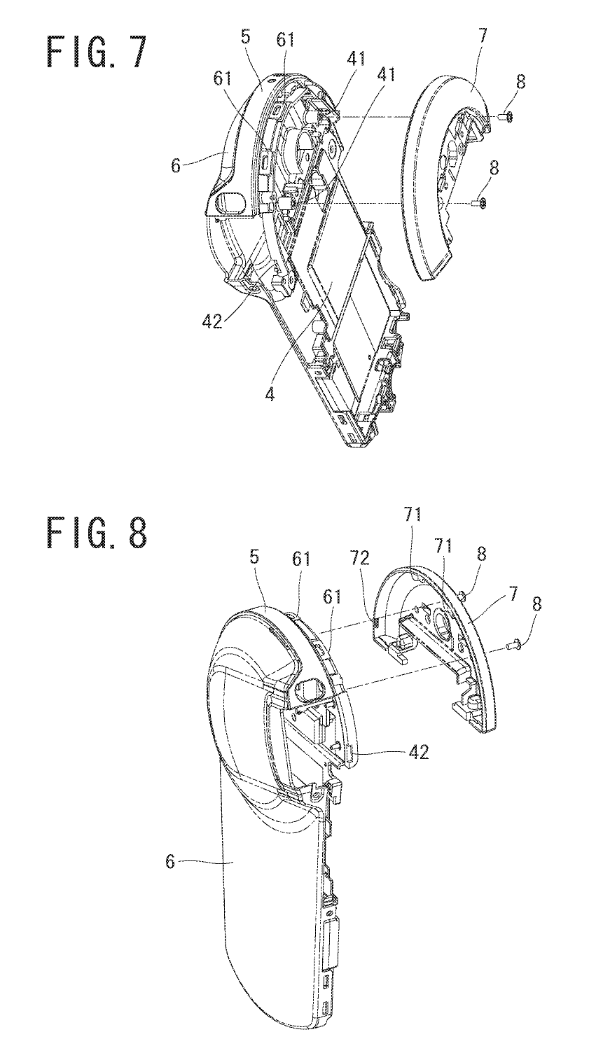

As illustrated in FIG. 6, an engagement receiving hole 51 which one engagement protrusion 72 can be elastically engaged with or disengaged from is formed at an end part of the intermediate cabinet component 5. Further, as illustrated in FIGS. 7 and 8, an engagement receiving concave portion 42 which the other engagement protrusion 72 can be elastically engaged with or disengaged from is formed at an end part of the chassis 4.

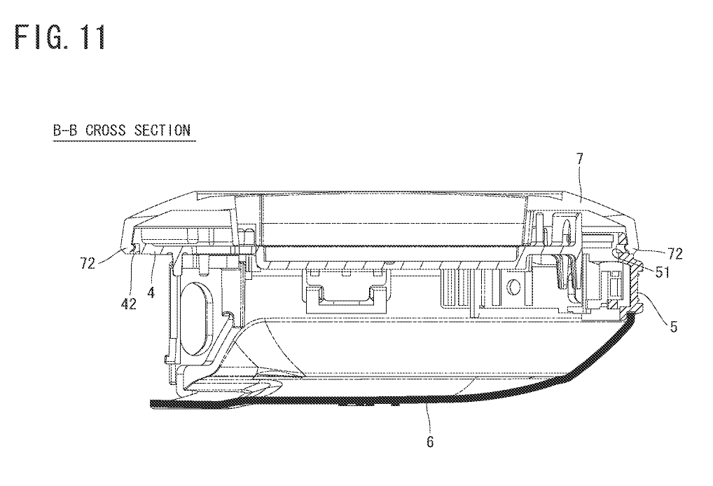

As illustrated in FIG. 11, by disengageably engaging the engagement protrusions 72 and 72 of the resin cabinet component 7 in the engagement receiving hole 51 of the intermediate cabinet component 5 and the engagement receiving concave portion 42 of the chassis 4, respectively, the two end parts of the resin cabinet component 7 are softly latched to the intermediate cabinet component 5 and the chassis 4.

Further, the resin cabinet component 7 is fastened to the chassis 4 using two screws 8 and 8. The two screws 8 and 8 penetrate the resin cabinet component 7 and, as illustrated in FIG. 7, the distal end parts of the two screws 8 and 8 screw into two bosses 41 and 41 that are protrudingly provided on the chassis 4.

In the assembly process of the video camera described above, first, as illustrated in FIG. 6, after the intermediate cabinet component 5 and the metal cabinet component 6 have been attached to the chassis 4, the resin cabinet component 7 is temporarily fixed to the metal cabinet component 6 and the chassis 4. Finally the resin cabinet component 7 is fastened to the chassis 4 using the two screws 8 and 8.

In the process of temporarily fixing the resin cabinet component 7 to the metal cabinet component 6 and the chassis 4, first the latching claws 71 and 71 of the resin cabinet component 7 are engaged in the respective latching holes 61a and 61a of the tongue pieces 61 and 61 of the metal cabinet component 6. In that state, the resin cabinet component 7 is pressed against a side face of the intermediate cabinet component 5 and the chassis 4. As a result, the engagement protrusions 72 and 72 of the resin cabinet component 7 elastically engage with the engagement receiving hole 51 of the intermediate cabinet component 5 and the engagement receiving concave portion 42 of the chassis 4, respectively, to thereby complete the temporary fixing.

As illustrated in FIG. 10, in this temporarily fixed state, the latching claw 71 of the resin cabinet component 7 penetrates the latching hole 61a from the outer side of the tongue piece 61 of the metal cabinet component 6, and aided by the elasticity contributed by the resin cabinet component 7 itself, the end part of the resin cabinet component 7 is securely latched to the end part of the metal cabinet component 6.

This latched state is not an engagement that can be elastically engaged and disengaged, and even if a large force which would cause the resin cabinet component 7 to separate from the metal cabinet component 6 acts, that force is securely received by the tongue piece 61 that is made of metal, and the latching is not released.

Further, as illustrated in FIG. 11, the engagement protrusions 72 and 72 of the resin cabinet component 7 are engaged with the engagement receiving hole 51 of the intermediate cabinet component 5 and the engagement receiving concave portion 42 of the chassis 4, respectively, and the engaged state thereof acts in combination with the above described latched state to ensure that the metal cabinet component 6 and the resin cabinet component 7 are securely coupled with each other and looseness does not arise between the components.

When the resin cabinet component 7 is fastened to the chassis 4 by means of the two screws 8 and 8 in this state, the latching claws 71 of the resin cabinet component 7 draw the metal cabinet component 6 further inward so that a clearance between the metal cabinet component 6 and the resin cabinet component 7 narrows and the intermediate cabinet component 5 is firmly sandwiched between the metal cabinet component 6 and the resin cabinet component 7.

As a result, the intermediate cabinet component 5, the metal cabinet component 6, and the resin cabinet component 7 are united without an assembling error occurring, to thereby construct the first casing 1.

As described above, according to the casing structure of an electronic apparatus according to an embodiment of the present invention, in the assembly process thereof, first, for the purpose of temporary fixing, the latching claws 71 of the resin cabinet component 7 may be caused to penetrate the latching holes 61a from the outer side of the tongue pieces 61 of the metal cabinet component 6 towards the inner side of the casing 1. Thus, since it is not necessary to perform an engagement operation that utilizes elasticity, the assembly work is simple and, likewise, disassembly is also simple. Further, in the fastening work performed thereafter using screws 8, it is only necessary to screw in two screws 8 and 8, and hence the work is simple.

It is to be understood that the present invention is not limited to the respective components and configuration described in the above embodiment and that various modifications will be apparent to those skilled in the art without departing from the spirit or scope of the following claims. For example, the present invention is not limited to a casing structure in which the first casing is made from three cabinet components, namely, an intermediate cabinet component, a metal cabinet component, and a resin cabinet component, and it is also possible to implement the present invention with respect to a casing structure that includes two cabinet components, namely, a metal cabinet component and a resin cabinet component, and from which an intermediate cabinet component is omitted.

What is claimed is:

1. A casing structure of an electronic apparatus in which a chassis to which a plurality of components are to be mounted is installed inside a casing, the casing comprising a metal cabinet component and a resin cabinet component that are provided on two sides of the chassis so as to be coupled with each other, wherein:
one or a plurality of tongue pieces that protrude in a direction approaching the resin cabinet component are formed in the metal cabinet component, and a latching hole is formed in each tongue piece;
one or a plurality of latching claws that are capable of penetrating the latching hole of the one or a plurality of tongue pieces are provided in a condition protruding toward a casing end part in the resin cabinet component, and the resin cabinet component is latched to the metal cabinet component by the latching claw penetrating the latching hole from an outer side of the tongue piece towards an inner side of the casing; and
the resin cabinet component is fastened to the chassis by one or a plurality of screws.

2. The casing structure according to claim 1, wherein an intermediate cabinet component is latched to the chassis, and the intermediate cabinet component is sandwiched between the metal cabinet component and the resin cabinet component.

3. The casing structure according to claim 2, wherein one or a plurality of engagement protrusions that protrude towards the inner side of the casing are formed in the resin cabinet component, and one or a plurality of engagement receiving portions which the one or a plurality of engagement protrusions can be elastically engaged with or disengaged from are recessed into the chassis and/or the intermediate cabinet component.

4. The casing structure according to claim 1, wherein the metal cabinet component is latched by a hook mechanism to the chassis.
